(19) United States
(12) Patent Application Publication
(10) Pub. No.: US 2005/0170608 A1
(43) Pub. Date: Aug. 4, 2005

(54) Semiconductor device and, manufacturing method thereof

(76) Inventors: Masahiro Kiyotoshi, Kanagawa (JP); Atsuko Kawasaki, Kanagawa (JP); Katsuhiko Hieda, Kanagawa (JP)

Correspondence Address: Finnegan, Henderson, Farabow,;Garrett & Dunner, L.L.P., 1300 I Street, N.W., Washington, DC, 20005-3315, US

(21) Appl. No.: 10/989,319

(22) Filed: Nov. 17, 2004

(30) Foreign Application Priority Data
Nov. 18, 2003 (JP) 2003-387657

(51) Int. Cl. H01L 21/76

(52) U.S. Cl. 438/427

(57) ABSTRACT

A semiconductor device comprises a semiconductor substrate; a trench formed on the semiconductor substrate; and an isolation region filled in the trench, the isolation region having a lower wet etching rate near the upper edge of said trench than that of the lower portion of said trench, and the wet etching rate of the isolation region being almost uniform on a plane parallel to the surface of the semiconductor substrate.

### CROSS-REFERENCE TO RELATED APPLICATIONS

This application is based upon and claims the benefit of priority from the prior Japanese Patent Applications NO. 2003-387657 filed on Nov. 18, 2003, the entire contents of which are incorporated herein by reference.

### BACKGROUND OF THE INVENTION

1. Field of the Invention

This invention relates to a semiconductor device and a manufacturing method thereof.

2. Related Art

A shallow trench isolation (STI) technology has been used for scale down of LSI. A trench and an insulating material with which the trench is filled are technology elements for the STI structure. Recently, the aperture width of the trench has been scaled down to from approximately 50 nm to approximately 70 nm, and it is ensured that further scale-down in the aperture width of the trench will be realized.

On the other hand, in order to maintain electric insulating effects between element regions, the depth of the trench for the STI structure is required to be maintained at an approximately constant one. That is, the aspect ratio of the trench for the STI structure has been increased every generation, because the depth is approximately constant in spite of further scale-down in the trench width.

In order to fill the trench with the insulating material, a high density plasma (HDP) CVD method has been commonly used. However, when the insulating material is embedded in the trench with a high aspect ratio by the HDP CVD method, a problem, that a void is generated in the trench, occurs. In order to solve the problem, a technology by which a material with fluidity such as a silicon oxide film (hereafter, called an SOG film) formed by spin on glass (SOG) processing, or a silicon oxide film (hereafter, called an O₃/TEOS film) formed by the CVD method using O₃ and tetraethoxy silane (TEOS) is embedded in the trench has been proposed.

The SOG film or the O₃/TEOS film has a lower film density, that is, a smaller amount of silicon for each unit volume in comparison with those of a silicon oxide film formed by the HDP-CVD method.

For example, an SOG film (hereafter, called a polysilazane film) which is formed by spin coating with a perhydrosilazane polymer has a lower film density by approximately 15% in comparison with that of the silicon oxide film formed by the HDP-CVD method. Accordingly, when the polysilazane film is deposited on a flat substrate by the spin coating method, the deposit amount of the polysilazane film is shrunk by equal to or larger than 15% by heat-treating after deposition. Here, a SOG film and an O₃/TEOS film of other materials have a similar shrinking tendency by heat-treating.

When the aperture width of the trench is comparatively large (for example, equal to or larger than 100 nm), the insulating material filled in the trench is shrunk in the vertical direction to the surface of the substrate as shown in FIG. 23. Therefore, the density of the insulating material can be consolidated by heat-treating to the same one as that of the silicon oxide film by the HDP-CVD method. However, when the aperture width of the trench is comparatively small (for example, equal to or smaller than 100 nm), the insulating material filled in the trench should be also shrunk in the vertical direction to the surface of the sidewall of the trench as shown in FIG. 23. However, the movement of the insulating material is limited by the sidewall of the trench. Further, as the aperture width is narrow, the insulating material on the upper portion of the trench is not drawn into the trench. Accordingly, when the aperture width of the trench is small, the insulating material in the trench can not be consolidated.

Therefore, when the trench with large aperture width and the trench with small width are formed on the same substrate, both of the etching rates are different from each other, because both of the densities of the insulating materials filled in the insides are also different from each other. Especially, the difference in the etching rates is remarkable in wet etching. As a result, the etched depths of the insulating materials are different from each other, depending on the aperture width of the trench, as shown in FIG. 24. Thus, there has been a problem that shape control is difficult in the STI structure.

Moreover, in the case of the trench with small aperture width, the insulating material near the side wall has a lower film density in comparison with that in the intermediate portion because the movement of the insulating material is limited by the side wall. Accordingly, the insulating material near the sidewall has a larger etching rate in comparison with that in the intermediate portion of the aperture of the trench. Therefore, the insulating material is etched so that it is deeply depressed near the sidewall as shown in FIG. 24. Thereafter, when an electrode is processed after polysilicon for the electrode is deposited, there is a possibility that a short circuit is occurred between adjacent devices because the polysilicon remains in the depression.

In order to consolidate the insulating material in the trench, reflow of the insulating material is considered. When the insulating material is a silicon oxide film, heat-treating of the substrate at high temperatures equal to or higher than 1150 degrees, or in an atmosphere of steam such as pyrogenic steam oxidation is required for reflow of the silicon oxide film.

When only the STI structure is considered, heating of the substrate at equal to or higher than 1150 degrees is not a problem. However, in the case of a logic element with embedded DRAM, or a semiconductor device forming both a gate oxide film and a gate electrode before the heat-treating, heating of the substrate at equal to or higher than 1150 degrees is not allowed. The reason is that the impurity concentration of the channel in a transistor is changed by the heat-treating.

Moreover, reflow of the silicon oxide film can be realized even under a low temperature of equal to or lower than 1150 degrees, because the transition point of the silicon oxide film is decreased by heat-treating of the substrate in an atmosphere of steam such as pyrogenic steam oxidation. However, the inside surface of the lower portion of the trench is also oxidized during oxidation in the steam atmosphere. As shown in FIG. 24, a bird's beak is caused in an element region, because the inner surface at the lower portion of the trench is oxidized though an etching region is an insulating material near the upper end of the trench among the insulating materials. Accordingly, the area of the element region is reduced. Moreover, there has been another problem that a crystal defect is generated in the element region because stresses occur in the element region while the inner surface of the trench is oxidized.

### SUMMARY OF THE INVENTION

A semiconductor device according to an embodiment of the present invention comprises a semiconductor substrate; a trench formed on the semiconductor substrate; and an isolation region filled in the trench, the isolation region having a slower wet etching rate near the upper edge of said trench than that of the lower portion of said trench.

A semiconductor device according to another embodiment of the present invention comprises a semiconductor substrate; a trench formed on the semiconductor substrate; and an isolation region filled in the trench, the isolation region having a higher film density near the upper edge of said trench than that near the lower portion of said trench.

A manufacturing method of a semiconductor device according to an embodiment of the present invention comprises: forming a trench on a semiconductor substrate, the trench being used for an isolation; embedding an insulating material in the trench; and heat-treating the insulating material in an atmosphere which includes at least one kind or more than one kind among a water radical, a heavy water radical, an OH radical and an OD radical, the atmosphere having a reduced pressure lower than atmospheric pressure.

A manufacturing method of a semiconductor device according to an embodiment of the present invention comprises: forming a plurality of trench capacitors for DRAMs; forming a trench for an isolation between the adjacent trench capacitors; embedding an insulating material in the trench; heat-treating the insulating material in an atmosphere which includes at least one kind or more than one kind among a water radical, a heavy water radical, an OH radical, or an OD radical, the atmosphere having a reduced pressure lower than atmospheric pressure.

### BRIEF DESCRIPTION OF THE DRAWINGS

FIG. 1 is a sectional view showing a processing flow of a manufacturing method of a semiconductor device according to a first embodiment of the present invention;

FIG. 2 is a sectional view showing a processing flow of a manufacturing method of a semiconductor device following FIG. 1;

FIG. 3 is a sectional view showing a processing flow of a manufacturing method of a semiconductor device following FIG. 2;

FIG. 4 is a sectional view showing a processing flow of a manufacturing method of a semiconductor device following FIG. 3;

FIG. 5 is a sectional view showing a processing flow of a manufacturing method of a semiconductor device following FIG. 4;

FIG. 6 is a sectional view showing a processing flow of a manufacturing method of a semiconductor device following FIG. 5;

FIG. 7 is a sectional view showing a processing flow of a manufacturing method of a semiconductor device following FIG. 6;

FIG. 8 is a table showing comparisons between the wet etching ratios of the O₃/TEOS film 160 heat-treated according to the present embodiment and those of the silicon oxide film heat-treated according to other known methods;

FIG. 9 is a sectional view showing a processing flow of a manufacturing method of a semiconductor device according to a second embodiment of the present invention;

FIG. 10 is a sectional view showing a processing flow of a manufacturing method of a semiconductor device following FIG. 9;

FIG. 11 is a sectional view showing a processing flow of a manufacturing method of a semiconductor device following FIG. 10;

FIG. 12 is a sectional view showing a processing flow of a manufacturing method of a semiconductor device following FIG. 11;

FIG. 13 is a sectional view showing a processing flow of a manufacturing method of a semiconductor device following FIG. 12;

FIG. 14 is a sectional view showing a processing flow of a manufacturing method of a semiconductor device following FIG. 13;

FIG. 15 is a sectional view showing a processing flow of a manufacturing method of a semiconductor device following FIG. 14;

FIG. 16 is a sectional view showing a processing flow of a manufacturing method of a semiconductor device according to a third embodiment of the present invention;

FIG. 17 is a sectional view showing a processing flow of a manufacturing method of a semiconductor device following FIG. 16;

FIG. 18 is a sectional view showing a processing flow of a manufacturing method of a semiconductor device following FIG. 17;

FIG. 19 is a sectional view showing a processing flow of a manufacturing method of a semiconductor device following FIG. 18;

FIG. 20 is a sectional view showing a processing flow of a manufacturing method of a semiconductor device following FIG. 19;

FIG. 21 is a sectional view of an element which is oxidized in a dry oxygen atmosphere at a temperature of 1000 degrees instead of the heat-treating with radicals;

FIG. 22 is a sectional view of an element which is oxidized in an atmosphere of water vapor at a temperature of 1000 degrees instead of the heat-treating with radicals;

FIG. 23 is a sectional view of a trench in which an insulating material is shrunk by a heat-treating according to a conventional art; and

FIG. 24 is a sectional view of a trench in which the insulating material is etched after the heat-treating shown in FIG. 23.

### DETAILED DESCRIPTION OF THE INVENTION

Hereafter, embodiments according to the present invention will be explained by referring to drawings. The invention is not limited to the following embodiments.

In these embodiments, an insulating material in an STI structure is heat-treated by using a radical. By the heat-treating, reflow of the insulating material near the upper end of a trench is executed at a comparatively low temperature, and that of the lower portion of the trench is not done, regardless of the size of the aperture width of the trench. Accordingly, the insulating material only near the upper end of the trench can be consolidated regardless of the aperture width of the trench.

(First Embodiment)

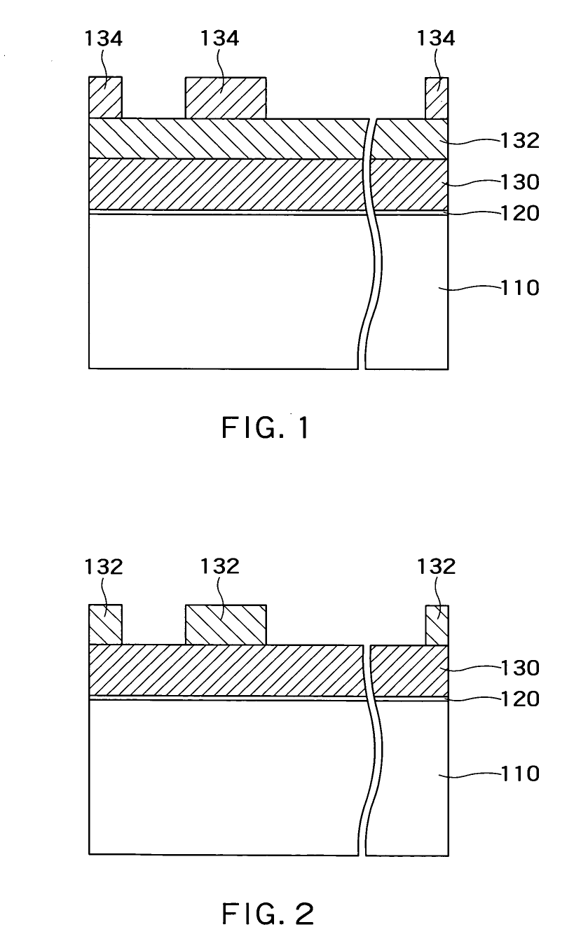

FIGS. 1 through 7 are sectional views showing a processing flow of a manufacturing method of a semiconductor device according to a first embodiment of the present invention. In FIGS. 1 through 7, an STI structure formed by a trench with a small aperture width (for example, equal to or smaller than 100 nm) is shown on the left side, and another STI structure formed by a trench with a large aperture width (for example, exceeding 100 nm) is shown on the right side.

In the first place, a thermal oxide film 120 is formed on the surface of a semiconductor substrate 110 to a thickness of approximately 5 nm as shown in FIG. 1. Then, a silicon nitride film 130 is deposited on the thermal oxide film 120 to a thickness of 150 nm. Subsequently, a silicone oxide film 132 is deposited on the silicon nitride film 130 according to a CVD (Chemical Vapor Deposition) method. Then, a photoresist film 134 is applied onto the silicon oxide film 132. The photoresist film 134 is patterned, using a photolithography technology.

As shown in FIG. 2, the silicon oxide film 132 is etched by a reactive ion etching (RIE) method by using the patterned photoresist film 134 as a mask. Therafter, the photoresist film 134 is removed.

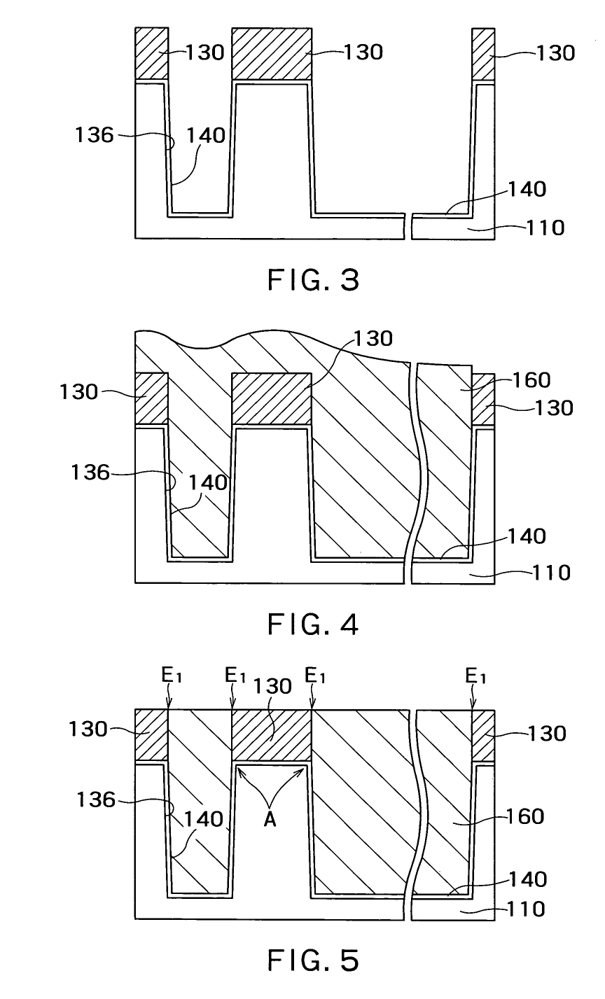

As shown in FIG. 3, the silicon nitride film 130, the thermal oxide film 120, and the semiconductor substrate 110 are etched one by one by the RIE method, using the silicon oxide film 132 as a mask. At this time, a groove with a depth of approximately 300 nm from the surface of the semiconductor substrate 110 is formed. Then, the silicon oxide film 132 is removed by hydrofluoric acid vapor. Subsequently, a thermal oxide film 140 of approximately 4 nm is formed by thermal oxidation of the inner surface of the groove. Thus, a trench 136 with a comparatively small aperture width, and a trench 137 with a comparatively large aperture width are formed.

As shown in FIG. 4, an O₃/TEOS film 160 is deposited on the semiconductor substrate 110. Deposition of the O₃/TEOS film 160 is formed at a temperature of 450 degrees under a pressure of 100 Torr. The trench 136 can be embedded with the O₃/TEOS film 160 without voids (not filled) because of the flowability of the film. Then, the O₃/TEOS film 160 is heat-treated. For example, the O₃/TEOS film 160 is heat-treated at a high temperature of 900 degrees for 60 minutes in an atmosphere of dry oxygen.

As shown in FIG. 5, the O₃/TEOS film 160 is polished by a chemical mechanical polishing (CMP) technology, using the silicon nitride film 130 as a CMP stopper. Thereby, the surface of the O₃/TEOS film 160 is planarization while the O₃/TEOS film 160 remains within the trenches 136 and 137.

Subsequently, the O₃/TEOS film 160 is heat-treated with a water radical and an OH radical. The heat-treating process is executed as follows. In the first place, the semiconductor substrate 110 is carried into a reactor, and the semiconductor substrate 110 is heated to approximately 850 degrees with a lamp heater. Then, the water radical and the OH radical are introduced into the reactor. Water-vapor gas as a material for the water radical and OH radical is produced by evaporation of pure water with a evaporator. The supply rate (flow rate) of the pure water is 5 standard litters per minute (SLMs) on a gas basis. The water-vapor gas is excited by micro wave discharging of approximately 2.45 GHz to generate an active water radical and an active OH radical. In an atmosphere including the water radical and the OH radical, the O₃/TEOS film 160 is heat-treated for approximately 15 minutes under an atmospheric pressure of approximately 1 Torr. As the heat-treating is executed in an atmosphere at a pressure much lower than the atmospheric pressure, the water radical, the OH radical, or the water vapor is diffused into near the upper ends E₁ of the trenches 136 and 137 among the O₃/TEOS film 160, but not into the inside of the trenches 136 and 137 among the O₃/TEOS film 160. For example, the water radical, the OH radical, or the water vapor is diffused into the O₃/TEOS film 160 in contact with the silicon nitride film 130 shown in FIG. 5, but not into the O₃/TEOS films 160 near the thermal oxide film 140 and the semiconductor substrate 110. Moreover, the strong activity of the water radical and the OH radical causes strong reaction to the O₃/TEOS films 160 near the upper ends E₁ in the trenches 136 and 137. However, as most of the water radical and the OH radical loses the activity near the surface of the O₃/TEOS film 160, they hardly react to the O₃/TEOS films 160 near the thermal oxide film 140 and the semiconductor substrate 110.

When the water radical or the radical OH are introduced into the O₃/TEOS films 160 near the upper ends E₁ of the trenches 136 and 137, the glass transition temperature of the O₃/TEOS film 160 is decreased to a temperature lower than the ordinary glass transition temperature (approximately 1150 degrees) by approximately 300 degrees. As a result, the heat-treating can melt the O₃/TEOS films 160 near the upper ends E₁ of the trenches 136 and 137 to consolidate the film 160. On the other hand, the O₃/TEOS films 160 near the thermal oxide film 140 and the semiconductor substrate 110 have an ordinary glass transition temperature (approximately 1150 degrees). Thereby, the O₃/TEOS films 160 near the thermal oxide film 140 and the semiconductor substrate 110 are not melted. Therefore, the O₃/TEOS films 160 near the thermal oxide film 140 and the semiconductor substrate 110 maintain the low film density.

Accordingly, the O₃/TEOS films 160 near the upper ends E₁ of the trenches 136 and 137 have the similar film density as that of the silicon oxide film formed by an HDP-CVD method. Moreover, as the water radical and the OH radical react only to the O₃/TEOS film 160 near the surface regardless of the aperture width of the trench, the O₃/TEOS films 160 in the trenches 136 and 137 have an almost equal film density to each other. Furthermore, as the water radical and the OH radical do not reach the O₃/TEOS films 160 near the thermal oxide film 140 and the semiconductor substrate 110, the edges A of the element region is not oxidized. Therefore, as a bird's beak is not caused in the edges A of the element region, the area of the element region is not reduced.

Here, as only the O₃/TEOS films 160 near the upper ends of the trenches 136 and 137 are etched when a semiconductor element is formed in the element region, it is required to consolidate only the O₃/TEOS films 160 near the upper ends of the trenches 136 and 137. On the other hand, it is not required to consolidate the O₃/TEOS films 160 near the lower end in the trenches 136 and 137.

As shown in FIG. 6, wet etching of the O₃/TEOS film 160 is executed by using dilute hydrofluoric acids or buffered hydrofluoric acid. As the O₃/TEOS film 160 near the upper end of the trench 136 and that near the upper end of the trench 137 have the approximately same film density as each other, both the films 160 near the upper ends of the trenches 136 and 137 are almost uniformly etched, regardless of the aperture widths of the trenches 136 and 137. Accordingly, the height of the O₃/TEOS film 160 from the surfaces of the semiconductor substrate 110 can be easily controlled. Moreover, not only the O₃/TEOS film 160 in the trench 137, but also the O₃/TEOS film 160 in the trench 136 is etched almost uniformly in a plane parallel to the surface of the semiconductor substrate 110. This means that the O₃/TEOS film 160 is not etched in such a way that the film 160 is depressed near the side wall of the trench 136. Thereby, a short circuit is not occurred between polysilicon for a gate electrode, which is deposited after the above step, and the semiconductor substrate 110.

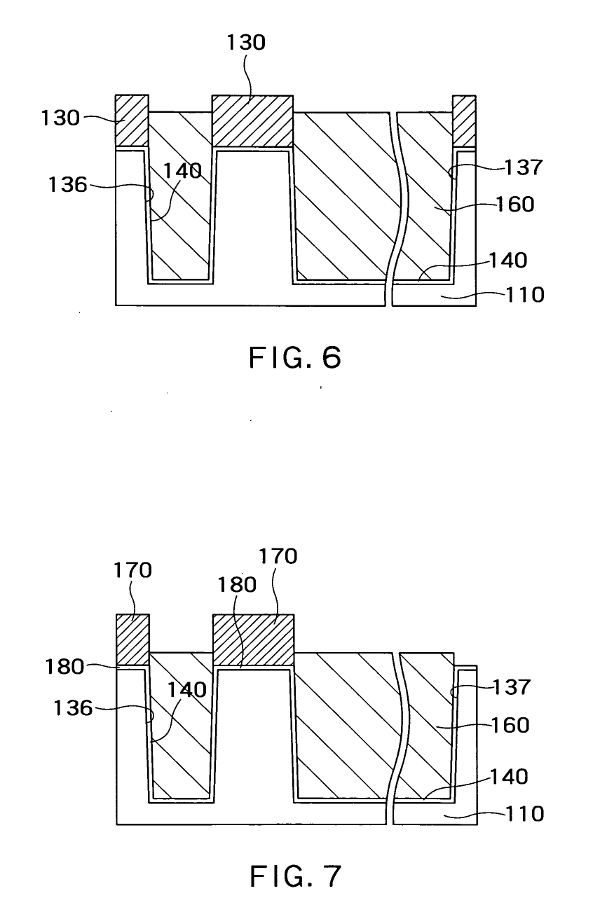

Then, the silicon nitride film 130 is removed with a heated phosphoric acid solution as shown in FIG. 7. The STI structure, which comprises the trenches 136 and 137, and the O₃/TEOS film 160, functions as an element isolation region between the element regions. The thermal oxide film 140 on the element region is removed, then, a gate insulating film 180 is formed on the element region. Subsequently, the gate electrode 170 is formed on the gate insulating film 180. The gate electrode 170 is made of, for example, a doped polysilicon. Moreover, diffusion layers (not shown) and the like are formed on the element regions to complete elements such as transistors.

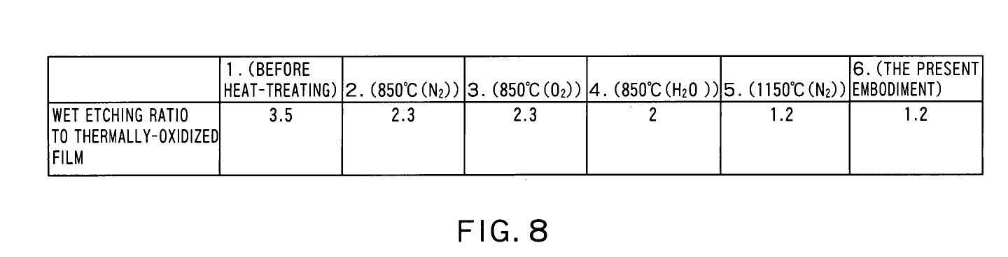

FIG. 8 is a table showing comparisons between the wet etching ratios of the O₃/TEOS film 160 heat-treated according to the present embodiment and those of the silicon oxide film heat-treated according to other known methods. The wet etching ratio means a ratio between the etching rate of a thermal oxide film and that of a silicon oxide film formed under conditions 1-6 at wet etching with a dilute hydrofluoric acid and a buffered hydrofluoric acid.

The wet etching ratio of the O₃/TEOS film is 3.5 before heat-treating immediately after deposition of the O₃/TEOS film (condition 1). When the O₃/TEOS film is heat-treated at 850 degrees in an atmosphere of nitrogen (condition 2), the wet etching ratio of the O₃/TEOS film is 2.3. When the O₃/TEOS film is heat-treated at 850 degrees in an atmosphere of oxygen (condition 3), the wet etching ratio of the O₃/TEOS film is 2.3. When the O₃/TEOS film is heat-treated at 850 degrees in an atmosphere of water vapor (condition 4), the wet etching ratio of the O₃/TEOS film is 2. When the O₃/TEOS film is heat-treated at 1150 degrees in an atmosphere of nitrogen (condition 5), the wet etching ratio of the O₃/TEOS film is 1.2. According to the present embodiment (condition 6), the wet etching ratio of the O₃/TEOS film near the upper end of the trench 136 is 1.2.

Thus, almost the similar wet etching ratio as that of heat-treating at 1150 degrees in an atmosphere of nitrogen is obtained without heat-treating at a high temperature of approximately 1150 degrees in the present embodiment. This means that the present embodiment can be applied to a logic element with embedded DRAM, or a semiconductor device forming a gate oxide film before the heat-treating.

Though the O₃/TEOS film is used as an insulating film forming the STI structure in the present embodiment, the effects according to the embodiment is obtained even when an SOG film is used in stead of the O₃/TEOS film.

Though heat-treating with the water radical or OH radical is done at the step shown in FIG. 5 according to the present embodiment, a heavy water radical or OD (Deuterium Oxygen) radical, instead of the water radical or OH radical, may be used for heat-treating, wherein the heavy water radical or the OD radical is produced by reaction of heavy hydrogen and oxygen. Moreover, a water radical or a heavy water radical, which is produced from water or heavy water, may be used for heat-treating. Plasma radiation by a parallel plate plasma and an inductively-coupled plasma (ICP), or an ultraviolet radiation, and the like, other than the micro wave radiation, may be used as a method by which the water radical and the OH radical are produced from water vapor, a method by which the heavy water radical or the OD radical is produced from heavy hydrogen and oxygen, and a method by which the water radical or a heavy water radical is produced from water or heavy water.

The semiconductor device manufactured according to the present embodiment comprises the gate insulating film 180 formed on the element region, and the gate electrode 170 formed on the gate insulating film 180 as shown in FIG. 7. The diffusion layers formed in the element regions are omitted.

With regard to the O₃/TEOS film 160 filled in the trench 136, the etching rate of the O₃/TEOS film 160 from the upper end of the trench 136 to near the gate insulating film 180 is slower than that of the O₃/TEOS film 160 near the lower end of the trench 136. The reason is that the O₃/TEOS film 160 is consolidated in near the upper end of the trench 136, and, on the other hand, the film 160 is not consolidated in near the lower end of the trench 136, because the water radical and the OH radical have very strong oxidizability, and a characteristic to easily lose the activity.

Moreover, the O₃/TEOS film 160 has almost uniform etching rate on the plane parallel to the surface of the semiconductor substrate 110. That is, after wet etching, the O₃/TEOS film 160 has almost flat upper surface in the trench 136 without depressing as shown in FIG. 24.

(Second Embodiment)

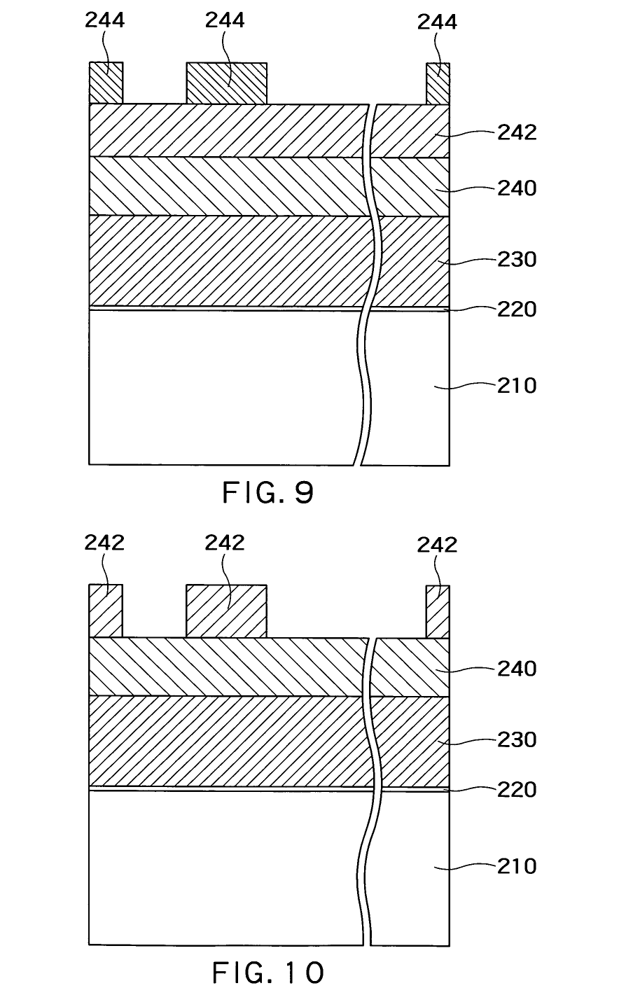

FIGS. 9 through 15 are sectional views showing a processing flow of a manufacturing method of a semiconductor device according to a second embodiment of the present invention. In the drawings shown in from FIG. 9 to FIG. 15, an STI structure formed by a trench with a small aperture width (for example, equal to or smaller than 100 nm) is shown on the left side, and another STI structure formed by a trench with a large aperture width (for example, exceeding 100 nm) is shown on the right side. In the embodiment, after a gate oxide film and a gate electrode are formed, an insulating material used for the STI structure is heat-treated.

In the first place, a gate oxide film 220 is formed on a semiconductor substrate 210 as shown in FIG. 9. A polysilicon film 230, a silicon nitride film 240, and a silicon oxide film 242 are deposited on the gate oxide film 220 one by one. Moreover, a photoresist film 244 is applied on the silicon oxide film 242. A photoresist film 244 is patterned, using a photolithography technology.

As shown in FIG. 10, the silicon oxide film 242 is etched by an RIE method by using the patterned photoresist film 244 as a mask.

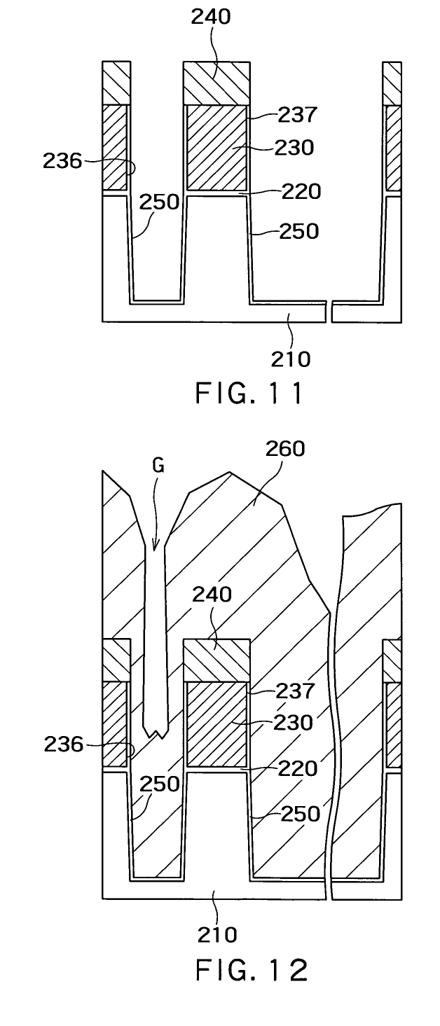

As shown in FIG. 11, the silicon nitride film 240, the polysilicon film 230, the gate oxide film 220, and the semiconductor substrate 210 are etched by the RIE method one by one by using the silicon oxide film 242 as a hard mask. At this time a groove with a depth of approximately 200 nm from the surface of the semiconductor substrate 210 is formed. Then, the silicon oxide film 242 is removed by hydrofluoric acid vapor. Subsequently, a thermal oxide film 250 of approximately 4 nm is formed by thermal oxidation of the inner surface of the groove. Thus, a trench 236 with a comparatively small aperture width and a trench 237 with a comparatively large aperture width are formed.

As shown in FIG. 12, a silicon oxide film 260 is deposited on the semiconductor substrate 210 by an HDP-CVD method. The processing is stopped before a void is generated in the trench 236. Accordingly, though the trench 237 with a large aperture width is filled with the silicon oxide film 260, a slit-type gap G remains in the trench 236 with a small aperture width. The aspect ratio of the gap G is very large (for example, equal to or larger than 10). Thereby, it is difficult to fill the silicon oxide film in the gap G by the HDP-CVD method without generating a void.

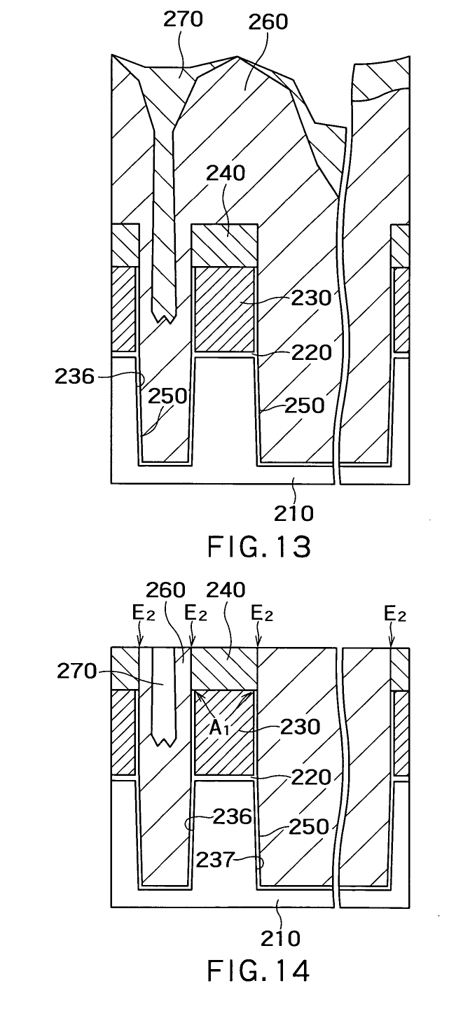

Accordingly, a polysilazane film 270 is applied onto the silicon oxide film 260 by the spin coating method as shown in FIG. 13. The polysilazane film 270 is formed as follows. A perhydrogenated silazane (perhydrosilazane) polymer (SiH₂NH)ₙ is dispersed into xylene, dibutyl ether, and the like to produce the perhydrosilazane polymer solution. Subsequently, the perhydrosilazane polymer solution is applied onto the silicon oxide film 260 by the spin coating method. As the viscosity of the perhydrosilazane polymer solution is low, the perhydrosilazane polymer solution can be filled in the gap G with a high aspect ratio with generating neither void nor seam.

A concrete example of steps from applying the perhydrosilazane polymer solution to forming the polysilazane film 270 will be shown as follows. Conditions for the spin coating are assumed to be, for example, that the rotation speed of the semiconductor substrate 210 is 4000 rpm, the rotation time is 30 seconds, and the drop amount of the perhydrosilazane polymer solution is 8 cc. Thereby, the perhydrosilazane polymer solution can be applied, for example, with a film thickness of 200 nm in a flat region. Then, the perhydrosilazane polymer solution is heated to 180 degrees, and is heat-treated for three minutes in an atmosphere of inert gas. Thereby, a solvent in the perhydrosilazane polymer solution is volatilized. Subsequently, the applied film is oxidized in an oxidizing atmosphere at a temperature of from 300 degrees to 400 degrees. Thereby, impurity carbon and hydrocarbon in the applied film are removed, and, at the same time, a part of Si—N bond is converted to Si—O bond. This reaction proceeds as follows: SiH₂NH+2O→SiO₂+NH₃. Here, the wet etching rate is reduced by the conversion from the Si—N bond to the Si—O bond, though the permittivity of the applied film is also reduced by the conversion. Therefore, it is required to consider heat-treating conditions in such a way that the Si—N bond is not converted to the Si—O bond more than necessity. In a representative example, the applied film is oxidized for 30 minutes under a normal pressure in a dry oxygen atmosphere at a temperature of 380 degrees. Subsequently, the applied film is heat-treated for 60 minutes in a dry oxygen atmosphere at a temperature of 850 degrees. Thereby, the polysilazane film 270 is formed. The polysilazane film 270 is a silicon oxynitride film including approximately 2% nitrogen.

Then, as shown in FIG. 14, the polysilazane film 270 and the silicon oxide film 260 are polished by the CMP technology by using the silicon nitride film 240 as a stopper. Thereby, the polysilazane film 270 and the silicon oxide film 260 remain only in the trenches 236 and 237.

Subsequently, the polysilazane film 270 and the silicon oxide film 260 (hereafter, called embedded films 260 and 270) are heat-treated by using radicals. Hereafter, a concrete example for the above heat-treating will be explained. The semiconductor substrate 210 is carried into a vacuum chamber, and the substrate 210 is heated to approximately 1000 degrees with a lamp heater or a single-slice type heating unit such as a hot plate. Then, hydrogen gas is introduced into a reactor with a flow rate of 8 SLMs, and oxygen gas is introduced therein with a flow rate of 15 SLMs. The hydrogen gas and the oxygen gas react to each other on the surface of the heated semiconductor substrate 210 to produce an active water radical and an active OH radical with water vapor. The embedded films 260 and 270 are heat-treated for approximately 20 seconds under a pressure of approximately 9 Torr in an atmosphere including the water radical and the OH radical. As the processing is executed only for a short time in a reduced-pressure atmosphere, the water radical, the OH radical and the water vapor are diffused near the upper ends E₂ of the trenches 236 and 237 in the embedded films 260 and 270, and are not done into the inside of the trenches 236 and 237. For example, the water radical, the OH radical and the water vapor are diffused into the embedded films 260 and 270 in contact with the silicon oxide film 240 shown in FIG. 14, but is not diffused into the embedded films 260 and 270 near the polysilicon film 230, a gate insulating film 220 and the semiconductor substrate 210. Furthermore, the strong activity of the water radical and the OH radical causes strong reaction to the embedded films 260 and 270 near the upper ends E₂ in the trenches 236 and 237. However, as most of the water radical and the OH radical loses the activity near the surface of the embedded films 260 and 270, they hardly react to the embedded films 260 and 270 near the polysilicon film 230, the gate insulating film 220 and the semiconductor substrate 210.

When the water radical and the OH radical are diffused into the embedded films 260 and 270 near the upper ends E₂ of the trenches 236 and 237, the glass transition temperature of the polysilazane film 270 is lower than an ordinary one (approximately 1150 degrees) by approximately 100 degrees. As a result, the polysilazane film 270 near the end E₂ can be melted and consolidated. On the other hand, the polysilazane film 270 near the polysilicon film 230, the gate insulating film 220, and the semiconductor substrate 210 maintains the ordinary glass transition temperature (approximately 1150 degrees). Accordingly, the polysilazane film 270 near the polysilicon film 230, the gate insulating film 220, and the semiconductor substrate 210 is not melted and maintains the low film density.

Thereby, the polysilazane film 270 near the end E₂ has the same degree of the film density as that of the silicon oxide film 260 formed by the HDP-CVD method. Moreover, as the water radical and the OH radical react only to the O₃/TEOS film 160 near the surface regardless of the aperture width of the trench, the O₃/TEOS films 160 in the trenches 136 and 137 have an almost equal film density to each other. Furthermore, as the water radical and the OH radical do not reach the embedded films 260 and 270 near the polysilicon film 230, the gate insulating film 220 and the semiconductor substrate 210, the edges A₁ of the element region and the polysilicon film 230 are not oxidized. Accordingly, as a bird's beak is not caused in the edges A₁ of the element region, the area of the element region is not reduced. Moreover, the polysilicon film 230 acting as a gate electrode is not oxidized by these radicals.

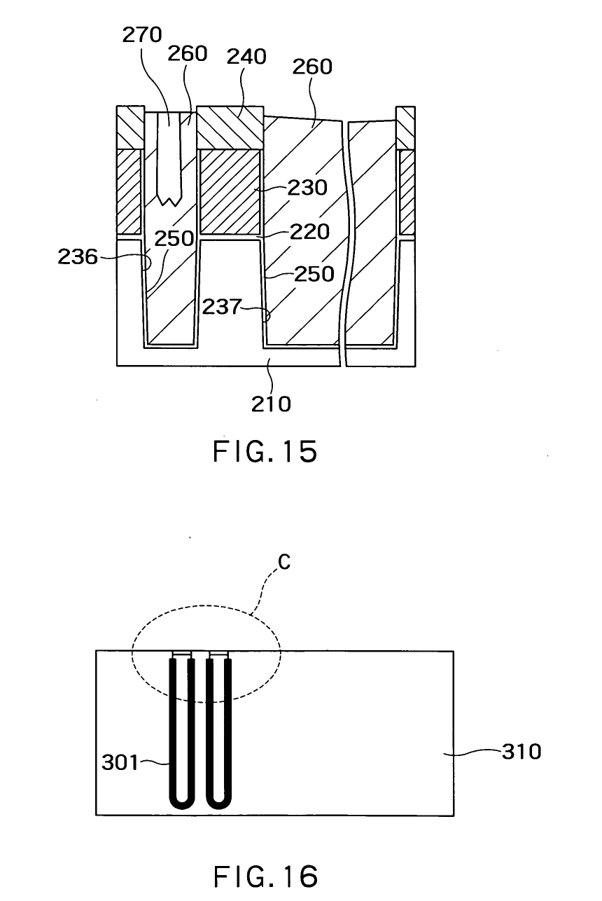

Then, the embedded films 260 and 270 are etched with a dilute hydrofluoric acid as shown in FIG. 15. As the upper portion of the polysilazane 270 is consolidated to the same extent as that of the silicon oxide film 260 formed by the HDP-CVD, both the etching amounts of the embedded films 260 and 270 are almost equal to each other. Thereby, the etching amounts of the embedded films 260 and 270 are controlled in wet etching to cause no difference between the level of the silicon oxide film 260 and that of the polysilazane 270. That is, the embedded films 260 and 270 can be etched flat.

Subsequently, the silicon nitride film 240 is removed with a heat phosphoric acid solution. The STI structure, which comprises the trenches 236 and 237, and the embedded films 260 and 270, functions as an element isolation region between the element regions. Furthermore, the polysilicon film 230 is processed to form diffusion layers and the like for completion of a semiconductor element.

Though the embedded film comprising the silicon oxide film 260 and the polysilazane 270 is used in the present embodiment, other SOG films or a O₃/TEOS film, in stead of the polysilazane film 270, may be used, and an HTO (High Temperature Oxide) film, instead of the silicon oxide film 260, may be used to yield the same effects as those of the embodiment. Moreover, even when a single-layer film comprising a polysilazane film, instead of the composite film comprising the silicon oxide film 260 and the polysilazane 270, is used, the same effects as those of the embodiment may be obtained.

Though the water radical or the OH radical is used for heat treatment at the step shown in FIG. 14 in the present embodiment, a heavy water radical or an OD radical produced by reaction of heavy hydrogen and oxygen, instead of the water radical or the OH radical, may be used for the heat treatment. Further, a water radical or a heavy water radical produced from water or heavy water may be used for the heat treatment. Plasma radiation by parallel plate plasma and inductive coupling plasma (ICP), or ultraviolet radiation, and the like, other than the micro wave radiation, may be used as a method by which the water radical and the OH radical are produced from water vapor, a method by which the heavy water radical or the OD radical is produced from heavy hydrogen and oxygen, and a method by which the water radical or the heavy water radical is produced from water or heavy water. The embodiment has the same effects as those of the first embodiment, other than the above-described effects.

(Third Embodiment)

FIGS. 16 through 20 are sectional views showing a processing flow of a manufacturing method of a semiconductor device according to a third embodiment of the present invention. The present embodiment is a method according which a logic device with embedded DRAM is manufactured. FIGS. 16 through 20 show steps through which an STI structure is formed after a trench capacitor 301 is formed.

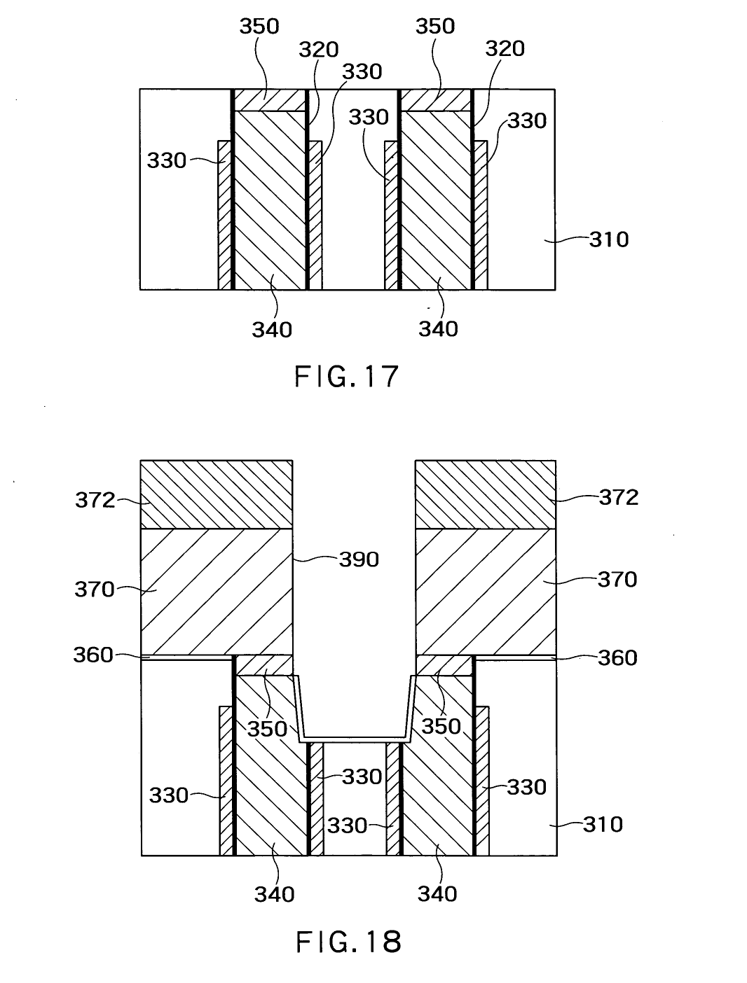

In the first place, the trench capacitor 301 is formed in a semiconductor substrate 310 as shown in FIG. 16. FIG. 17 is a enlarged sectional view of a configuration within a circle C indicated by a dashed line in FIG. 16. The trench capacitor 301 comprises: a diffusion layer 330 which acts as a plate electrode; a NO (silicon nitride-silicon oxide) film 320 of a dielectric film; a polysilicon film 340 which acts as a charge storage node; and a silicon oxide film 350. In order to control excessive diffusion of the diffusion layer 330, it is required to limit a processing temperature at a heating step after the trench capacitor is formed.

Then, a silicon oxide film 360 is formed on the surface of the semiconductor substrate 310 as shown in FIG. 18. A silicon nitride film 370, and a silicon oxide film 372 are deposited on the silicon oxide film 360 one by one. The silicon oxide film 372 is processed by a photolithography technology and an RIE method to form a hard mask. The silicon nitride film 370, the silicon oxide film 360, a part of the trench capacitor 320 and the semiconductor substrate 310 are etched one by one by the RIE method by using the silicon oxide film 372. At this time, a groove with a depth of approximately 250 nm from the surface of the semiconductor substrate 310 is formed.

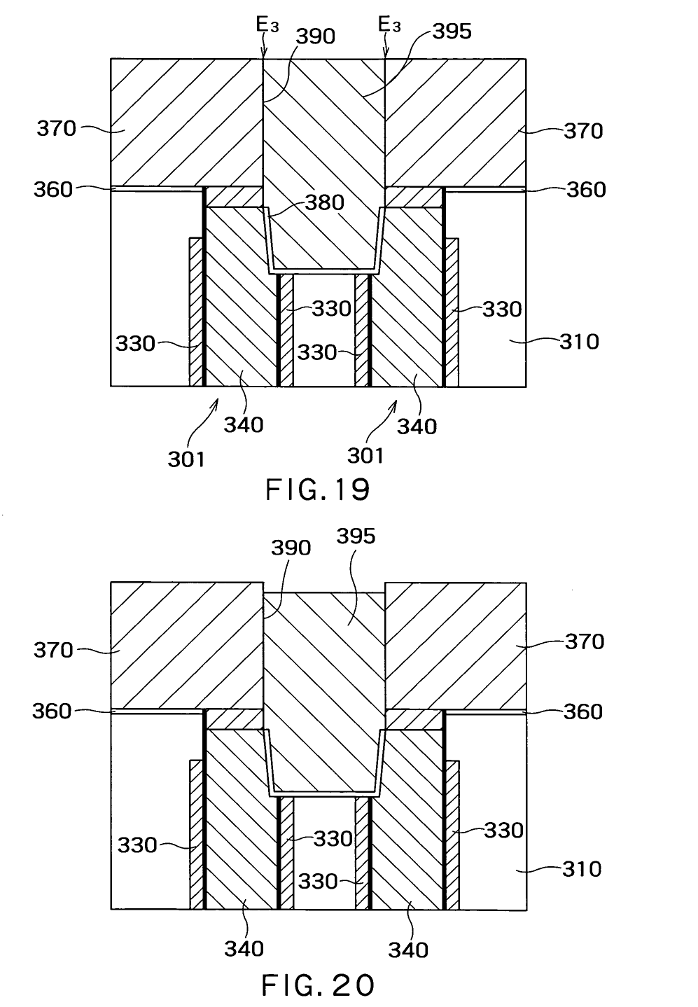

Subsequently, the silicon oxide film 372 is removed with hydrofluoric acid vapor as shown in FIG. 19. Then, a thermal oxide film 380 of approximately 4 nm is formed by thermal oxidation of the inner surface of the groove. Thus, a trench 390 is formed.

Then, a polysilazane film 395 is applied on the semiconductor substrate 310 by a spin coating method. The polysilazane film is formed in the similar manner to that of the second embodiment. Or, though the applied film is oxidized for 30 minutes under a normal pressure in a dry oxygen atmosphere at a temperature of 380 degrees in the above-described example, the applied film may be oxidized for 20 minutes in an atmosphere of water vapor at a temperature of 330 degrees. Thereby, the polysilazane film 395 becomes a silicon oxide film including nitrogen of equal to or less than 0.1%.

Subsequently, the polysilazane film 395 is polished by a CMP technology by using the silicon nitride film 370 as a stopper. Thereby, the polysilazane film 395 remains only in the trench 390.

Then, the polysilazane film 395 is heat-treated by using a heavy water radical or OD radical. Hereafter, a concrete example for the above heat-treating will be explained. The semiconductor substrate 310 is carried into a reactor, while the substrate 310 is mounted on a quartz boat. In this reactor, the semiconductor substrate 310 is heated to a temperature of 900 degrees at a heating rate of 80 degrees/minute under an atmospheric pressure of approximately 5 Torr in an atmosphere of nitrogen. Subsequently, heavy hydrogen gas is introduced into the reactor with a flow rate of 3 SLMs, and oxygen gas is introduced into the reactor with a flow rate of 6 SLMs. The heavy hydrogen gas and the oxygen gas are reacted to each other in the reactor to produce an active heavy water radical and an active OD radical along with heavy water vapor. In an atmosphere including the heavy water radical and the OD radical, the polysilazane film 395 is heat-treated for approximately three minutes. As the processing is executed only for a short time in a reduced-pressure atmosphere, the heavy water radical, the OD radical and the water vapor are diffused near the upper end E₃ of the trench 390 in the polysilazane films 395, but are not diffused to the inside of the trench 390. Furthermore, the strong activity of the heavy water radical and the OD radical causes strong reaction to the polysilazane film 395 near the upper ends E₃ in the trench 390. However, as most of the heavy water radical and the OD radical lose the activity near the surface of the polysilazane film 395, they hardly react to the polysilazane film 395 near the trench capacitor 301 and the semiconductor substrate 310.

When the heavy water radical and the OD radical are diffused into the polysilazane film 395 near the upper edges E₃ of the trench 390, the glass transition temperature of the polysilazane film 395 becomes lower than an ordinary one (approximately 1150 degrees) by approximately 200 degrees. As a result, the polysilazane film 395 near the edges E₃ can be melted, and consolidated. On the other hand, the polysilazane film 395 near the trench capacitor 301 and the semiconductor substrate 310 maintains the ordinary transition point (approximately 1150 degrees). Accordingly, the polysilazane film 395 near the trench capacitor 301 and the semiconductor substrate 310 is not melted and maintains the low film density.

Thereby, the polysilazane film 395 near the edges E₃ has the same degree of the film density as that of the silicon oxide film formed by an HDP-CVD method. Moreover, as the heavy water radical and the OD radical do not reach the polysilazane film 395 near the trench capacitor 301 and the semiconductor substrate 310, the trench capacitor 301 is not oxidized. Accordingly, as a bird's beak is not caused in the trench capacitor 301, the characteristics of the trench capacitor 301 are not changed.

Then, the polysilazane film 395 is etched with a dilute hydrofluoric acid as shown in FIG. 20. As the upper portion of the polysilazane film 395 is consolidated to the same extent as that of the silicon oxide film formed by the HDP-CVD, the etching amount of the polysilazane film 395 is almost equal to that of the silicon oxide film formed by the HDP-CVD. Furthermore, the polysilazane film 395 can be etched flat.

Then, the silicon nitride film 370 is removed with a heat phosphoric acid solution. The STI structure, which comprises the trench 390 and the polysilazane film 395, acts as an element separation section between the trench capacitors 301. Furthermore, a logic device with embedded DRAM is manufactured for completion, using known steps.

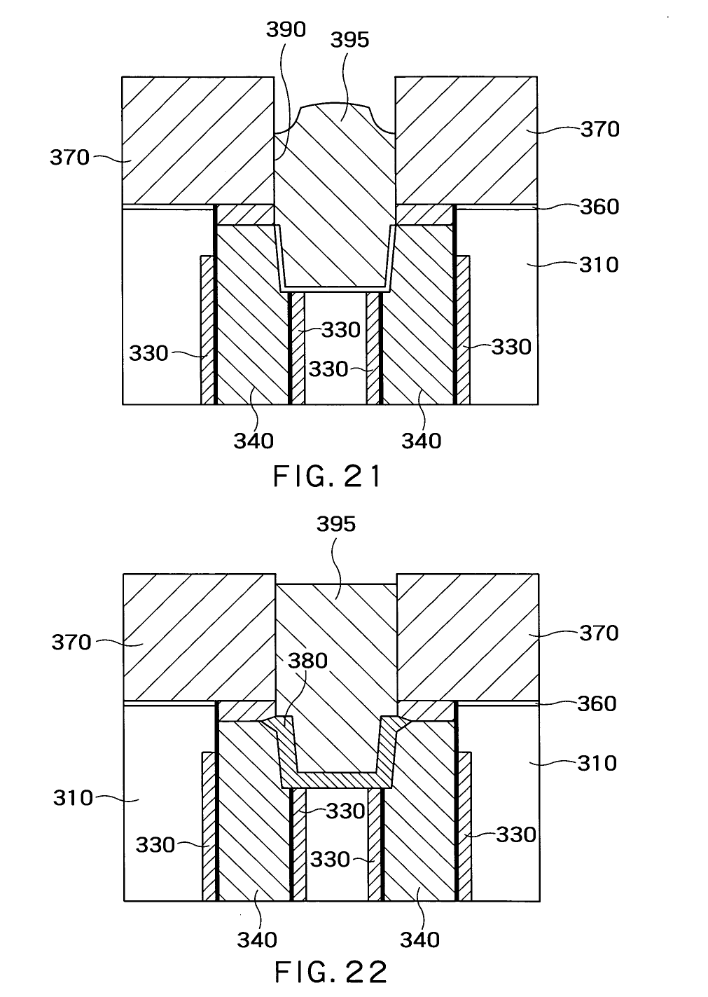

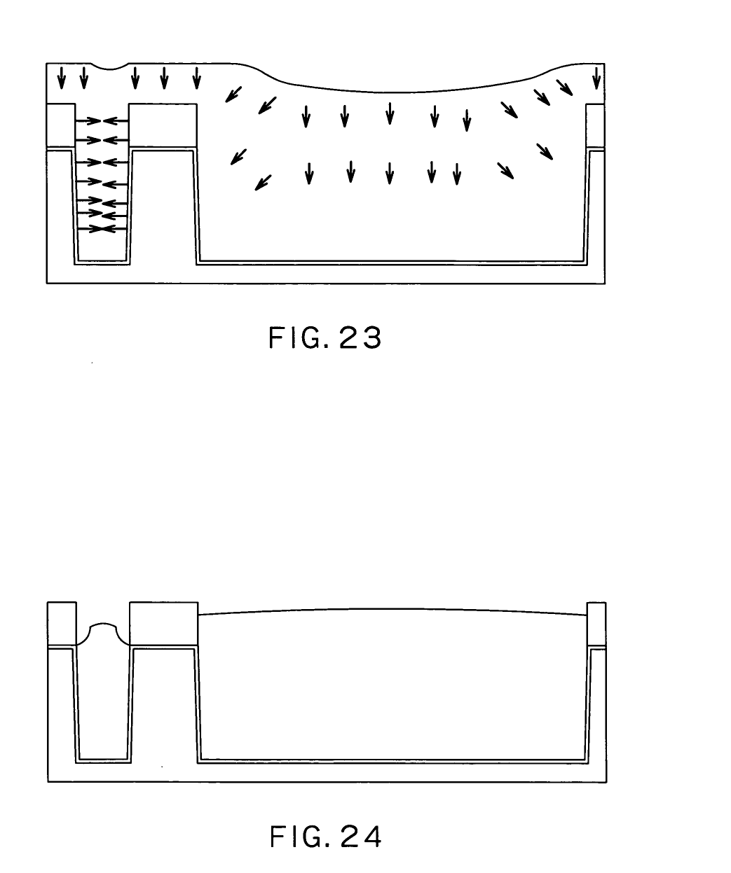

FIG. 21 is a sectional view of an element which is oxidized in a dry oxygen atmosphere at a temperature of 1000 degrees instead of the heat-treating with radicals in the present embodiment. FIG. 22 is a sectional view of an element which is oxidized in an atmosphere of water vapor at a temperature of 1000 degrees instead of the heat-treating with radicals. FIGS. 21 and 22 are associated with FIG. 20 in the present embodiment, and shows a state after the polysilazane film is etched with the dilute hydrofluoric acid. The advantages of the present embodiment are cleared by comparing FIG. 20 with FIGS. 21 and 22.

In the STI structure shown in FIG. 21, the polysilazane film 395 is etched so that it is depressed near the sidewall of the trench 390. In the STI structure shown in FIG. 22, the side wall of the trench 390 is oxidized, and the film thickness of the thermal oxide film 380 is greatly increased. Moreover, a bird's beak is generated in the trench capacitor 301.

On the other hand, when heat-treating with the radicals is executed according to the present embodiment shown in FIG. 20, the surface of the polysilazane film is etched flat, and the side wall of the trench 390 is not oxidized.

Though the polysilazane film 395 is used as an insulating material which fills the trench 390 in the embodiment, other SOG films or O₃/TEOS films, in stead of the polysilazane film 395, may be used. Moreover, though the polysilazane film 395 is a single-layer film in the present embodiment, a composite film comprising a polysilazane film and a silicon oxide film formed by the HDP-CVD, or another composite film comprising a polysilazane film and an HTO film, instead of the film 395, may be applied. In an atmosphere of water vapor, the polysilazane film 395 may be heat-treated at a temperature of 600 degrees and may be converted to a silicon oxide film.

Though heat-treating is executed with the heavy water radical or the OD radical in the step shown in FIG. 19 in the present embodiment, a water radical or an OH radical, instead of the radicals at the step in FIG. 19, may be used for the heat-treating, wherein the water radical and the OH radical are produced by reaction between hydrogen and oxygen. Moreover, a water radical or a heavy water radical, which are produced by reaction water or heavy water, may be used for the heat treating. Plasma radiation by parallel plate plasma and inductive coupling plasma (ICP), or ultraviolet radiation, and the like, other than the micro wave radiation, may be used as a method by which the water radical and the OH radical are produced from water vapor, a method by which the heavy water radical or the OD radical is produced from heavy hydrogen and oxygen, and a method by which the water radical or the heavy water radical is produced from water or heavy water. The present embodiment has the same effects as those of the first embodiment, other than the above-described effects.

As the second and third embodiments use polysilazane which is an inorganic material, pollution of a semiconductor substrate by carbon can be better controlled in comparison with a semiconductor device which uses an organic SOG film or an organic O₃/TEOS film as an insulating material for the STI structure. Thereby, the reverse break-down voltage in an STI region can be improved to prevent junction leak in the STI region.

The trench 390 in the third embodiment may be embedded by a silicon oxide film and a polysilazane film by means of the second embodiment.

1. A semiconductor device comprising:
a semiconductor substrate;
a trench formed on the semiconductor substrate; and
an isolation region filled in the trench, the isolation region having a slower wet etching rate near the upper edge of said trench than that of the lower portion of said trench.

2. The semiconductor device according to claim 1, wherein the wet etching rate of the isolation region is almost uniform on a plane parallel to the surface of the semiconductor substrate.

3. The semiconductor device according to claim 1, wherein
the isolation region comprises a composite film including a SOG film formed by using a perhydrosilazane polymer and a silicon oxide film.

4. The semiconductor device according to claim 1, wherein
the semiconductor device has a logic device with embedded DRAMs,
wherein the trench and the isolation region are used to isolate between trench capacitors of the DRAMs.

5. The semiconductor device according to claim 3, wherein
the semiconductor device has a logic device with embedded DRAMs;
wherein the trench and the isolation region are used to isolate between trench capacitors of the DRAMs.

6. A semiconductor device comprising:
a semiconductor substrate;
a trench formed on the semiconductor substrate; and
an isolation region filled in the trench, the isolation region having a higher film density near the upper edge of said trench than that near the lower portion of said trench.

7. The semiconductor device according to claim 6, wherein the film density of the isolation region is almost uniform on a plane parallel to the surface of the semiconductor substrate.

8. A manufacturing method of a semiconductor device comprising:
forming a trench on a semiconductor substrate, the trench being used for an isolation;
embedding an insulating material in the trench; and
heat-treating the insulating material in an atmosphere which includes at least one kind or more than one kind among a water radical, a heavy water radical, an OH radical and an OD radical, the atmosphere having a reduced pressure lower than atmospheric pressure.

9. The manufacturing method of a semiconductor device according to claim 8, wherein;
the insulating material includes a film formed by using 03 and TEOS.

10. The manufacturing method of a semiconductor device according to claim 8, wherein;
the insulating material includes a film formed by applying a perhydrosilazane polymer (SiH₂NH)ₙ.

11. The manufacturing method of a semiconductor device according to claim 9, wherein;
the insulating material includes a film formed by applying a perhydrosilazane polymer (SiH₂NH)ₙ.

12. The manufacturing method of a semiconductor device according to claim 8 further comprising, while an insulating material is embedded in the trench;
depositing a silicon oxide film on an inner wall of the trench so that an aperture of the trench is not closed;
applying a perhydrosilazane polymer (SiH₂NH)ₙ on the silicon oxide film so that the trench is filled by the silicon oxide film and the perhydrosilazane polymer;
changing the perhydrosilazane polymer to a polysilazane film by a heat-treating.

13. The manufacturing method of a semiconductor device according to claim 8, wherein
the insulating material is wet-etched after the heat-treating of the insulating material.

14. A manufacturing method of a semiconductor device comprising:
forming a plurality of trench capacitors for DRAMs;
forming a trench for an isolation between the adjacent trench capacitors;
embedding an insulating material in the trench;
heat-treating the insulating material in an atmosphere which includes at least one kind or more than one kind among a water radical, a heavy water radical, an OH radical, or an OD radical, the atmosphere having a reduced pressure lower than atmospheric pressure.

15. The manufacturing method of a semiconductor device according to claim 14, wherein;
the insulating material includes a film formed by using O₃ and TEOS.

16. The manufacturing method of a semiconductor device according to claim 14, wherein;
the insulating material includes a film formed by applying a perhydrosilazane polymer (SiH₂NH)ₙ.

17. The manufacturing method of a semiconductor device according to claim 15, wherein;
the insulating material includes a film formed by applying a perhydrosilazane polymer (SiH₂NH)ₙ.

18. The manufacturing method of a semiconductor device according to claim 14 further comprising, while an insulating material is embedded in the trench;
depositing a silicon oxide film on an inner wall of the trench so that an aperture of the trench is not closed;
applying a perhydrosilazane polymer (SiH₂NH)ₙ on the silicon oxide film so that the trench is filled by the silicon oxide film and the perhydrosilazane polymer;
converting the perhydrosilazane polymer to a polysilazane film by a heat-treating.

19. The manufacturing method of a semiconductor device according to claim 14, wherein
the insulating material is wet-etched after the heat-treating of the insulating material.

20. The manufacturing method of a semiconductor device according to claim 14, wherein the insulating material near the upper edge of the trench is selectively consolidated by the heat-treating.
